(19) United States
(12) Patent Application Publication
(10) Pub. No.: US 2025/0290195 A1
(43) Pub. Date: Sep. 18, 2025

(54) MAGNETRON SPUTTERING DEVICE AND METHOD FOR AMORPHOUS CARBON FILM AND AMORPHOUS CARBON FILM FOR PHOTORESIST DEPOSITED USING THE SAME

(71) Applicant: BACO. SOLUTION.,CO.LTD., Hwaseong-si (KR)

(72) Inventor: Hyun Jong LEE, Hwaseong-si (KR)

(21) Appl. No.: 19/223,079

(22) Filed: May 30, 2025

Related U.S. Application Data
(63) Continuation of application No. PCT/KR2024/020172, filed on Dec. 10, 2024.

(30) Foreign Application Priority Data
Dec. 26, 2023 (KR) 10-2023-0191890

(51) Int. Cl. C23C 14/35; C23C 14/06; C23C 14/54; H01J 37/32; H01J 37/34; H01L 21/02

(52) U.S. Cl. CPC C23C 14/35; C23C 14/0605; C23C 14/54; H01J 37/32449; H01J 37/3405; H01J 37/3467; H01J 2237/332; H01L 21/02266

(57) ABSTRACT

Provided is a magnetron sputtering device for an amorphous carbon film. A magnetron sputtering device for an amorphous carbon film includes: a chamber having an inside maintained in a vacuum state and including a gas inlet through which a process gas is introduced and a gas outlet through which the process gas is discharged; a target unit including a target provided to face a deposition target substrate disposed inside the chamber and formed of amorphous carbon, and a magnetron disposed rearward of the target; and a control unit configured to selectively apply at least one of DC power and RF power to the target, in which a deposition film formed of the amorphous carbon is formed on the deposition target substrate through a first ignition mode, a second ignition mode, and a deposition mode which are sequentially switched, and the control unit simultaneously applies the DC power and the RF power to the target in the first ignition mode, and applies only the RF power to the target in the second ignition mode and the deposition mode.

### CROSS-REFERENCE TO RELATED APPLICATIONS

This application is a Continuation of Application No. PCT/KR2024/020172, filed on Dec. 10, 2024, which in turn claims the benefit of Korean Patent Application No. 10-2023-0191890, filed on Dec. 26, 2023. The entire disclosures of all these applications are hereby incorporated by reference.

### TECHNICAL FIELD

The present invention relates to a device and a method for magnetron sputtering of an amorphous carbon film and a photoresist amorphous carbon film deposited using the same, and more specifically, to a device and a method for magnetron sputtering of an amorphous carbon film, which may control a surface roughness of the deposited amorphous carbon film such that the deposited amorphous carbon film may be used as a photoresist in a chemical etching process, and a photoresist amorphous carbon film deposited using the same.

### BACKGROUND ART

A sputtering method generally generates plasma by using a substrate as a positive electrode under a gas pressure of 10 pa or less and a sputtering target formed of a composition of a deposition film, which is to be formed as a negative electrode, to cause a discharge between the positive electrode and the negative electrode, so that positive ions in the plasma collide with the sputtering target of the negative electrode, and accordingly, particles having a force of attraction between each other are accumulated on the substrate to form a deposition film.

The sputtering method is largely classified into a radio sputtering method using a high frequency and a frequency (RF) direct current (DC) sputtering method using a direct current according to the type of power-generating plasma.

Meanwhile, polyimide (PI), which is mainly used as a photoresist in a chemical etching process, may decompose at a high temperature, which may be a problem during the process.

On the other hand, carbon has high thermal stability, and thus can be stably used even in a high-temperature process.

In addition, carbon shows strong resistance to many chemical substances, which means that when the carbon is applied as a photoresist, it can be more firmly maintained in the chemical etching process.

According to the unique physical and chemical properties of carbon, a method for replacing polyimide (PI), which is used as a photoresist in the chemical etching process, with carbon is being found.

However, when carbon is deposited on the substrate by using a conventional sputtering device to form a carbon film, the surface roughness of the carbon film is much greater than the surface roughness required for the photoresist, so that it is difficult to replace polyimide.

Therefore, there is a need for a method capable of reducing the surface roughness of the carbon film to a level of photoresist such that the carbon film deposited through sputtering may be used as a photoresist film in the chemical etching process.

### DISCLOSURE

### Technical Problem

One technical problem to be solved by the present invention is to provide a device and a method for magnetron sputtering of an amorphous carbon film, which may control a surface roughness of a deposited amorphous carbon film such that the deposited amorphous carbon film may be used as a photoresist in a chemical etching process.

Another technical problem to be solved by the present invention is to provide a device and a method for magnetron sputtering of an amorphous carbon film, which can deposit a deposited film formed of amorphous carbon capable of replacing conventional photoresists.

The technical problems to be solved by the present invention are not limited to those described above.

### Technical Solution

To solve the above-described one technical the problem, present invention provides a magnetron sputtering device for an amorphous carbon film.

According to one embodiment, a magnetron sputtering device for an amorphous carbon film may include: a chamber having an inside maintained in a vacuum state and including a gas inlet through which a process gas is introduced and a gas outlet through which the process gas is discharged; a target unit including a target provided to face a deposition target substrate disposed inside the chamber and formed of amorphous carbon, and a magnetron disposed rearward of the target; and a control unit configured to selectively apply at least one of DC power and RF power to the target, in which a deposition film formed of the amorphous carbon may be formed on the deposition target substrate through a first ignition mode, a second ignition mode, and a deposition mode which are sequentially switched, and the control unit may simultaneously apply the DC power and the RF power to the target in the first ignition mode, and apply only the RF power to the target in the second ignition mode and the deposition mode.

According to one embodiment, among the first ignition mode, the second ignition mode, and the deposition mode, a time of the first ignition mode may be shortest and a time of the deposition mode may be longest.

According to one embodiment, in the first ignition mode, the RF power applied to the target may be relatively greater than the DC power applied to the target, and in the first ignition mode, the second ignition mode, and the deposition mode, magnitudes of the RF power applied to the target may be all the same.

According to one embodiment, a surface roughness (Ra) of the deposition film may be in a range of 4 Å to 8 Å.

According to one embodiment, the surface roughness (Ra) is reduced as an area of the deposition film decreases.

Meanwhile, the present invention provides a photoresist amorphous carbon film.

According to one embodiment, the photoresist amorphous carbon film may be deposited on a deposition target substrate through the magnetron sputtering device according to claim 1, and have a surface roughness (Ra) in a range of 4 Åto 8 Å.

In addition, the present invention provides a magnetron sputtering method for an amorphous carbon film.

According to one embodiment, the magnetron sputtering method may include: installing a target, which faces a deposition target substrate and is formed of amorphous carbon, and a magnetron disposed rearward the target inside the chamber; supplying a process gas into the chamber; and selectively applying at least one of DC power and RF power to the target, in which the selectively applying of the at least one power may include: a first ignition process of simultaneously applying the DC power and the RF power to the target; a second ignition process of applying only the RF power to the target after the first ignition process; and a deposition process of continuously applying only the RF power to the target after the second ignition process.

### Advantageous Effects

According to one embodiment, the magnetron sputtering device for an amorphous carbon film may include: a chamber having an inside maintained in a vacuum state and including a gas inlet through which a process gas is introduced and a gas outlet through which the process gas is discharged; a target unit including a target provided to face a deposition target substrate disposed inside the chamber and formed of amorphous carbon, and a magnetron disposed rearward of the target; and a control unit configured to selectively apply at least one of DC power and RF power to the target, in which a deposition film formed of the amorphous carbon may be formed on the deposition target substrate through a first ignition mode, a second ignition mode, and a deposition mode which are sequentially switched, and the control unit may simultaneously apply the DC power and the RF power to the target in the first ignition mode, and apply only the RF power to the target in the second ignition mode and the deposition mode.

Accordingly, it is possible to provide a device and a method for magnetron sputtering of an amorphous carbon film, which may control a surface roughness of a deposited amorphous carbon film such that the deposited amorphous carbon film may be used as a photoresist in a chemical etching process.

That is, according to the embodiment of the present invention, it is possible to provide a device and a method for magnetron sputtering of an amorphous carbon film, which may significantly reduce the surface roughness of the deposited amorphous carbon film, and accordingly, it is possible to provide a deposition film formed of amorphous carbon having excellent quality as a photoresist of a chemical etching process.

Thus, according to the embodiment of the present invention, etching quality may be improved.

In addition, according to the embodiment of the present invention, a material such as polyimide (PI) used as a photoresist may be replaced with amorphous carbon.

### DESCRIPTION OF DRAWINGS

FIG. 1 is a schematic view for explaining a magnetron sputtering device for an amorphous carbon film according to one embodiment of the present invention.

FIGS. 2 to 4 are reference views for explaining a control unit of the magnetron sputtering device for an amorphous carbon film according to one embodiment of the present invention.

FIG. 5 is cross-sectional and surface images of an amorphous carbon film deposited according to Examples 1 and 2 and Comparative Examples 1 and 2 of the present invention, which is photographed using an electron microscope.

FIGS. 6 and 7 are results of measuring a surface roughness for each area of the amorphous carbon film deposited according to Examples 1 and 2 and Comparative Examples 1 and 2 of the present invention.

FIGS. 8 and 9 are surface scan images for each area of the amorphous carbon film deposited according to Examples 1 and 2 and Comparative Examples 1 and 2 of the present invention. FIG. 10 is a Tropel (Warp/Bow/SBIR/SFOR/TTV) analysis result of the amorphous carbon film deposited according to Examples 1 and 2 and Comparative Examples 1 and 2 of the present invention.

FIG. 11 is a flowchart showing a process procedure of a magnetron sputtering method for an amorphous carbon film according to one embodiment of the present invention. FIG. 12 is a flowchart sequentially showing a detailed process of step S130 of FIG. 11.

### BEST MODE

Hereinafter, preferred embodiments of the present invention will be described in detail with reference to the accompanying drawings. However, the present invention may be embodied in different forms and should not be construed as limited to the embodiments set forth herein. Rather, the embodiments introduced herein are provided so that the disclosed contents may be thorough and complete and the spirit of the present invention may be sufficiently conveyed to those skilled in the art.

In the present specification, when a component is referred to as being on another component, it means that it may be formed directly on the other component or a third component may be interposed therebetween. In addition, in the drawings, the shapes and the sizes are exaggerated for effective explanation of the technical content.

In addition, it will be also understood that although the terms first, second, third, and the like may be used herein to describe various elements, these elements should not be limited by these terms. These terms are only used to distinguish one element from another element. Accordingly, a component mentioned as a first component in one embodiment may be mentioned as a second component in another embodiment. Embodiments explained and illustrated herein include their complementary counterparts. As used herein, the term “and/or” includes any and all combinations of one or more of the associated listed elements.

The singular expression also includes the plural meaning as long as it does not differently mean in the context. In addition, the terms “comprise”, “have” etc., of the description are used to indicate that there are features, numbers, steps, elements, or combinations thereof, and they should not exclude the possibilities of combination or addition of one or more features, numbers, or a operations, elements, combination thereof. Furthermore, it will be understood that when an element is referred to as being “connected” or “coupled” to another element, it may be directly connected or coupled to the other element or intervening elements may be present.

In addition, the terms “ . . . unit,” “ . . . or/er,” “module”, and the like used herein indicate a unit for processing at least one function or operation, which may be implemented by hardware, software, or a combination thereof.

In addition, when detailed descriptions of related known functions or constitutions are considered to unnecessarily cloud the gist of the present invention in describing the present invention below, the detailed descriptions will not be included.

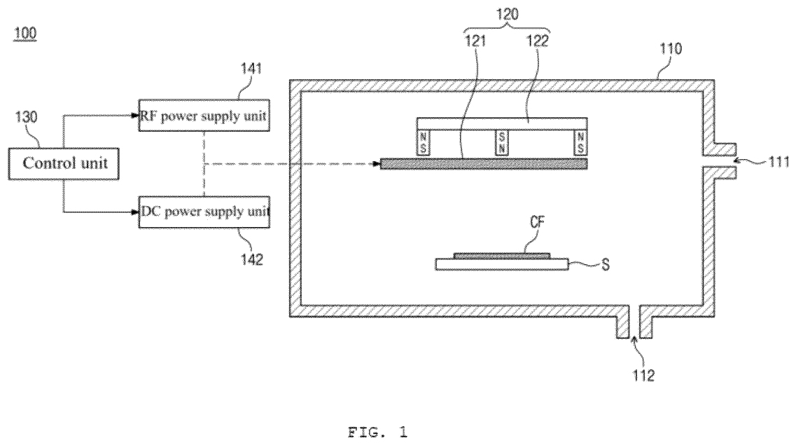

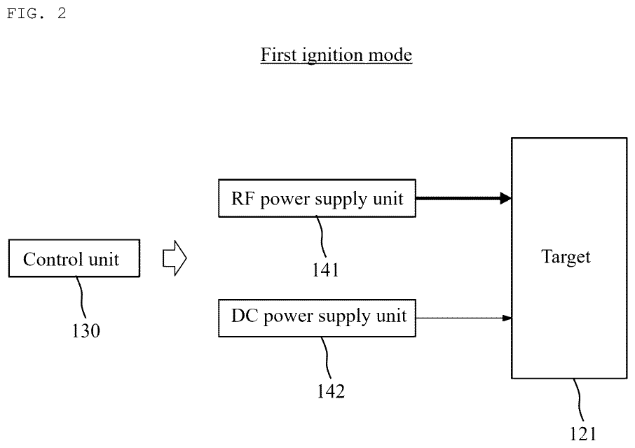

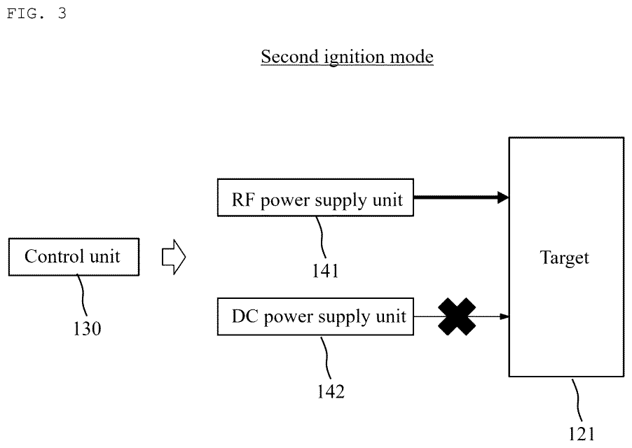

FIG. 1 is a schematic view for explaining a magnetron sputtering device for an amorphous carbon film according to one embodiment of the present invention, and FIGS. 2 to 4 are reference views for explaining a control unit of the magnetron sputtering device for an amorphous carbon film according to one embodiment of the present invention.

As shown in FIG. 1, a magnetron sputtering device 100 of an amorphous carbon film according to one embodiment of the present invention is a device for forming or making an amorphous carbon film CF, which is a deposition film, on a deposition target substrate S through sputtering.

In this case, the magnetron sputtering device 100 of an amorphous carbon film according to one embodiment of the present invention may control a surface roughness Ra of the amorphous carbon film CF deposited on the deposition target substrate S.

For example, the magnetron sputtering device 100 of an amorphous carbon film according to one embodiment of the present invention may control the surface roughness Ra of the amorphous carbon film CF deposited on the deposition target substrate S to be 4 Å to 8 Å.

In this case, a surface roughness Ra of a photoresist PR used in a chemical etching process is in a range of about 16 Å to 17 Å.

That is, the amorphous carbon film CF deposited on the deposition target substrate S through magnetron sputtering device 100 of an amorphous carbon film CF according to one embodiment of the present invention may have a surface roughness Ra lower than the surface roughness Ra of the general photoresist PR.

Accordingly, the amorphous carbon deposited on the deposition target substrate S through the magnetron sputtering device 100 of an amorphous carbon film according to one embodiment of the present invention may be replaced with, for example, polyimide (PI) used as the conventional photoresist PR.

As described above, when the amorphous carbon film CF deposited deposition target substrate S through the magnetron sputtering device 100 of an amorphous carbon film according to one embodiment of the present invention is used as the photoresist PR, due to high thermal stability and strong resistance to chemical substances, etching quality may be improved compared to a case where the amorphous carbon film CF is used as the photoresist PR formed of polyimide (PI).

To this end, the magnetron sputtering device 100 of an amorphous carbon film according to one embodiment of the present invention may include a chamber 110, a target unit 120, and a control unit 130.

The chamber 110 may provide an installation space of the deposition target substrate S and the target unit 120. To this end, the chamber 110 may be formed in a substantially hollow hexahedral shape. However, this is merely an example, and the chamber 110 may be formed in the shape of a hollow cylindrical tube.

In this case, the deposition target substrate S may provide a deposition surface on which particles separated from the target unit 120 are deposited during sputtering. In this case, since a target 121 of the target unit 120, which will be described later, is formed of amorphous carbon, the particles deposited on the deposition target substrate S during sputtering may be amorphous carbon particles.

Accordingly, the amorphous carbon film CF, which is a deposition formed of amorphous carbon, may be formed on the deposition target substrate S.

According to one embodiment of the present invention, the amorphous carbon film CF formed on the deposition target substrate S may be used as, for example, a photoresist PR of a semiconductor process.

Accordingly, the deposition target substrate S may be provided as a semiconductor wafer having a surface that is coated with the photoresist PR, for example, for a photolithography process.

However, this is merely an example, and the present invention does not particularly limit the deposition target substrate S to the semiconductor wafer.

For example, the deposition target substrate S on which the amorphous carbon film CF is deposited may include various types of glass, magnetic heads, electronic chips, electronic circuit boards, and materials similar thereto.

Although not shown, the deposition target substrate S may be supported while being mounted on a substrate holder. In this case, the substrate holder may be rotatably provided or laterally and movably provided.

Meanwhile, an inside of the chamber 110 may be maintained in a vacuum state. To this end, a vacuum pump (not shown) may be connected to the chamber 110 to create a vacuum state inside the chamber 110.

In addition, a gas inlet 111 through which a process gas is introduced may be provided on one side of the chamber 110, and a gas outlet 112 through which the process gas is discharged may be provided on the other side.

In this case, an inert gas may be used as the process gas. For example, an argon (Ar) gas may be used as the process gas.

According to one embodiment of the present invention, the target unit 120 may include the target 121 and a magnetron 122.

The target 121 may be provided in a substantially disc shape. The target 121 may be provided to face the deposition target substrate S disposed inside the chamber 110. In this case, the target 121 may be formed in an area relatively greater than the deposition target substrate S.

According to one embodiment of the present invention, the target 121 may be formed of amorphous carbon so that the amorphous carbon film CF, which is a deposition formed of amorphous carbon, is formed on the deposition target substrate S.

That is, when sputtering is performed, amorphous carbon particles forming the target 121 are separated from the target 121 and accumulated on the deposition target substrate S to form the amorphous carbon film CF.

In more detail, when the chamber 110 maintained in a vacuum atmosphere is filled with the argon (Ar) gas serving as the process gas and an electric field is formed between the target 121 and the deposition target substrate S, the argon (Ar) gas is ionized to generate plasma in the chamber 110, and argon (Ar) ions in the plasma are attracted toward an active surface of the target 121, that is, a surface of the target 121 facing the deposition target substrate S to collide with the active surface of the target 121. Due to the collision, the amorphous carbon particles are separated from the target 121 and move toward the deposition target substrate S, and are attached onto the deposition target substrate S to form the amorphous carbon film CF, which is a deposition film formed of amorphous carbon.

According to one embodiment of the present invention, the magnetron 122 may be disposed rearward of the target 121. The magnetron 122 may generate a magnetic field over the surface of the target 121 facing the deposition target substrate S, which is the active surface of the target 121.

As described above, the magnetic field generated by the magnetron 122 may trap the ionized process gas, for example, argon (Ar) ions and electrons, near the surface of the target 121 facing the deposition target substrate S in order to generate plasma.

Accordingly, a density of plasma may be increased near the surface of the target 121 facing the deposition target substrate S.

In this way, a deposition rate may be improved by the plasma density increased by the magnetic field.

In more detail, the magnetic field generated by the magnetron 122 moves while forming a closed curve toward the surface of the target 121 facing the deposition target substrate S, and as the electrons move, the electrons receive a Lorentz force to accelerate in a spiral motion.

For this reason, since the electrons near the target 121 do not deviate from the magnetic field and rotate around the magnetic field, a density of the electrons in the plasma increases, and accordingly, the electrons collide with the argon (Ar) ions more, thereby increasing the deposition rate.

According to one embodiment of the present invention, the magnetron 122 may be provided as a plurality of electromagnets or permanent magnets forming a magnetic array.

In this case, the magnetron 122 may be provided to be rotatable about one axis, and may perform a relative motion with respect to the target 121 through the rotational motion.

To this end, for example, the magnetron 122 may be connected to a power transmission unit such as a belt and a pulley to receive power from a power source.

Meanwhile, although not shown, the magnetron sputtering device 100 of an amorphous carbon film according to one embodiment of the present invention may further include a path guider.

The path guider may be installed between the deposition target substrate S and the target 121. The path guider may guide an emission path of the amorphous carbon particles such that amorphous carbon particles, which are not directed toward the deposition target substrate S among the amorphous carbon particles separated from the target 121 during sputtering, are directed toward the deposition target substrate S.

The path guider may be formed in a tubular shape with open upper and lower ends. In this case, the path guider may be provided in a form in which an inner diameter thereof gradually decreases toward the lower end. That is, an inner diameter surface of the path guider may be inclined downward in a direction toward the deposition target substrate S.

Accordingly, the probability that the amorphous carbon particles separated from the target 121 collide with the inner diameter surface of the path guider may be increased. Accordingly, the amorphous carbon particles may be deposited on the deposition target substrate S in a state where kinetic energy is reduced, thereby alleviating or minimizing a physical impact of the deposition target substrate S due to the amorphous carbon particles.

An RF power supply unit may be further provided on an outer circumferential surface of one side of the path guider. The RF power supply on one side of the path guider may create a high-density plasma environment such that the plasma has a high density near the target surface. Meanwhile, the control unit may control the RF power supply unit as described above, and may further control the RF power supply unit on the outer circumferential surface of one side of the path guider. According to one example, the control unit may turn off the RF power supply unit in a first ignition mode and a second ignition mode, and turn on the RF power supply in a deposition mode on the outer circumferential surface of one side of the path guider. Accordingly, the amorphous carbon film may be evenly deposited at a high deposition rate.

The control unit 130 may apply power to the target 121 such that an electric field for generating plasma generation in the chamber 110 is formed between the target 121 and the deposition target substrate S.

In this case, according to one embodiment of the present invention, the control unit 130 may selectively apply at least one power of a direct current (DC) power and a radio frequency (RF) power to the target 121 in order to control the surface roughness Ra of the amorphous carbon film CF deposited on the deposition target substrate S.

To this end, the magnetron sputtering device 100 of an amorphous carbon film according to one embodiment of the present invention may further include a RF power supply unit 141 and a DC power supply unit 142.

The RF power supply unit 141 may be electrically connected to the target 121. The RF power supply unit 141 may supply RF power to the target 121 according to a power application signal of the control unit 130.

In this case, the RF power supply unit 141 may be connected to the target 121 through, for example, an RF impedance match (not shown).

The DC power supply unit 142 may also be electrically connected to the target 121. The DC power supply unit 142 may supply DC power to the target 121 according to a power application signal of the control unit 130.

In this case, the DC power supply unit 142 may be connected to the target 121 through, for example, an RF block filter (not shown).

That is, the control unit 130 may selectively output a power application signal to at least one of the RF power supply unit 141 and the DC power supply unit 142, thereby simultaneously applying the DC power and the RF power or applying only the RF power to the target 121.

From another perspective, the control unit 130 may selectively apply the DC power while applying the RF power.

Meanwhile, the magnetron sputtering device 100 of an amorphous carbon film according to one embodiment of the present invention may form the amorphous carbon film CF, which is deposition formed of amorphous carbon, on the deposition target substrate S through the first ignition mode, the second ignition mode, and the deposition mode that are sequentially switched.

In this case, among the first ignition mode, the second ignition mode, and the deposition mode, a time of the first ignition mode may be shortest and a time of the deposition mode may be longest.

For example, the first ignition mode time may be set to 3 seconds. In addition, the second ignition mode time may be set to 5 seconds. In addition, the deposition mode time may be set to 400 seconds.

However, this is merely an example, and the time of each mode may be set to various times in which the first ignition mode time is set to be the shortest and the deposition mode time is set to be the longest.

According to one embodiment of the present invention, the control unit 130 may simultaneously apply the DC power and the RF power to the target 121 in the first ignition mode.

As shown in FIG. 2, in the first ignition mode, the control unit 130 may output a power application signal to both the RF power supply unit 141 and the DC power supply unit 142. Accordingly, the RF power supply unit 141 may supply the RF power to the target 121 in the first ignition mode. Simultaneously, the DC power supply unit 142 may also supply the DC power to the target 121.

In this case, according to one embodiment of the present invention, in the first ignition mode, the control unit 130 may output a power application signal, which is relatively greater than the power application signal output to the DC power supply unit 142, to the RF power supply unit 141.

Accordingly, in the first ignition mode, the RF power applied to the target 121 may be relatively greater than the DC power simultaneously applied.

For example, in the first ignition mode, when RF power of 600 W is applied to the target 121, DC power of 500 W may be simultaneously applied to the target 121 for 3 seconds.

In addition, the control unit 130 may apply only the RF power to the target 121 in the second ignition mode.

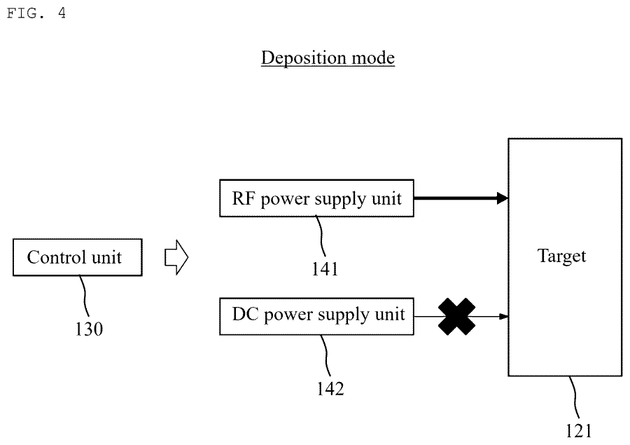

As shown in FIG. 3, in the second ignition mode, the control unit 130 may output a power application signal to only the RF power supply unit 141.

Accordingly, only the RF power supply unit 141 may be operated to supply the RF power to the target 121 in the second ignition mode.

For example, in the second ignition mode, RF power of 600 W may be applied to the target 121 for 5 seconds, and in this case, the DC power applied to the target 121 may be zero.

In addition, as in the second ignition mode, the control unit 130 may apply only the RF power to the target 121 in the deposition mode. In this case, since there is no change in the type and amount of power applied upon switching from the second ignition mode to the deposition mode, the second ignition mode and the deposition mode may be distinguished only in terms of a process.

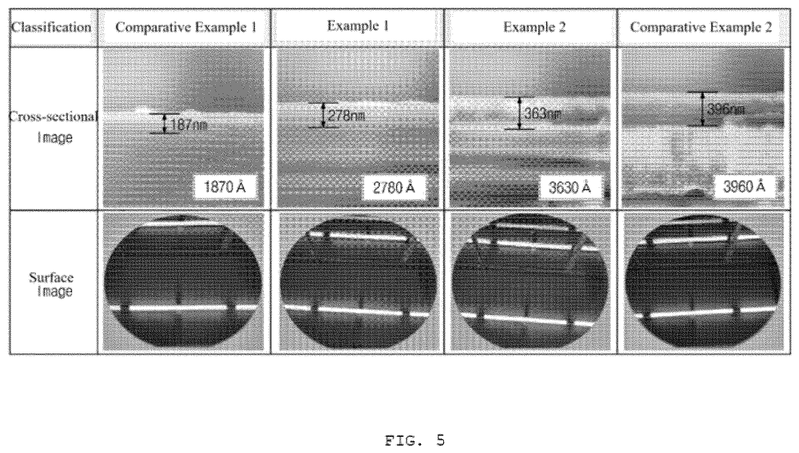

As shown in FIG. 4, in the deposition mode, the control unit 130 may output a power application signal to only the RF power supply unit 141.

Accordingly, only the RF power supply unit 141 may be operated to supply the RF power to the target 121 in the deposition mode.

For example, in the deposition mode, RF power of 600 W may be applied to the target 121 for 400 seconds, and in this case, the DC power applied to the target 121 may be zero.

As described above, according to one embodiment of the present invention, the DC power may be applied to the target 121 only in the first ignition mode. In addition, according to one embodiment of the present invention, the RF power may be applied to the target 121 at the same magnitude in all of the first ignition mode, the second ignition mode, and the deposition mode.

Accordingly, the RF power and the DC power may be simultaneously applied to the target 121 only in the first ignition mode in which sputtering is initially started, and only the RF power may be applied to the target 121 in the remaining modes. That is, while the RF power is applied in all modes, the DC power may be selectively applied.

According to one embodiment of the present invention, in the first ignition mode and the second ignition mode, plasma is generated by an electric field formed inside the chamber 110, and in the deposition mode, amorphous carbon particles forming the target 121 are separated from the target 121 and accumulated on the deposition target substrate S to form the amorphous carbon film CF.

As described above, the magnetron sputtering device 100 of an amorphous carbon film according to one embodiment of the present invention may deposit the amorphous carbon film CF on the deposition target substrate S through the control unit 130 that selectively applies at least one of the DC power and the RF power to the target 121 for each mode.

In this case, the amorphous carbon film CF deposited on the deposition target substrate S may have a surface roughness Ra in a range of 4 Å to 8 Å.

Since the surface roughness Ra of the photoresist PR used in the chemical etching process is in a range of about 16 Å to 17 Å, according to the present invention, the amorphous carbon film CF deposited on the deposition target substrate S may have a surface roughness Ra lower than a surface roughness Ra of the photoresist PR generally required.

Accordingly, the amorphous carbon film CF may replace a material such as polyimide (PI) used as the photoresist PR in the related art.

As described above, when the amorphous carbon film CF deposited on the deposition target substrate S through the magnetron sputtering device 100 of an amorphous carbon film according to one embodiment of the present invention is used as the photoresist PR of a chemical etching process, due to high thermal stability and strong resistance to chemical substances, etching quality may be improved compared to, for example, a case where the amorphous carbon film CF is used as the photoresist PR formed of polyimide (PI).

### Example 1

An amorphous carbon target was disposed to face a substrate and a magnetron was disposed rearward of the amorphous carbon target in a chamber, and then an argon gas was injected into the chamber while maintaining the inside of the chamber in a vacuum state. In the first ignition mode for sputtering, RF power of 600 W and DC power of 500 W were simultaneously applied to the amorphous carbon target for 3 seconds, in the second ignition mode, only RF power of 600 W was applied to the amorphous carbon target for 5 seconds, and in the deposition mode, only RF power of 600 W was applied to the amorphous carbon target for 400 seconds to perform the sputtering.

As a result of the sputtering, the amorphous carbon film was deposited on the substrate, and a deposition thickness was measured to be 2780 Å.

### Example 2

In a state where an internal atmosphere of the chamber was formed in the same manner as in Example 1, in the first ignition mode for sputtering, RF power of 800 W and DC power of 500 W were simultaneously applied to the amorphous carbon target for 3 seconds, in the second ignition mode, only RF power of 800 W was applied to the amorphous carbon target for 5 seconds, and in the deposition mode, only RF power of 800 W was applied to the amorphous carbon target for 400 seconds to perform the sputtering.

As a result of the sputtering, the amorphous carbon film was deposited on the substrate, and a deposition thickness was measured to be 3630 Å.

### Comparative Example 1

In a state where an internal atmosphere of the chamber was formed in the same manner as in Example 1, in the first ignition mode for sputtering, only DC power of 1500 W was simultaneously applied to the amorphous carbon target for 3 seconds, in the second ignition mode, RF power of 300 W and DC power of 1500 W were simultaneously applied to the amorphous carbon target for 5 seconds, and in the deposition mode, RF power of 300 W and DC power of 1500 W were simultaneously applied to the amorphous carbon target for 400 seconds to perform the sputtering.

As a result of the sputtering, the amorphous carbon film was deposited on the substrate, and a deposition thickness was measured to be 1870 Å.

### Comparative Example 2

In a state where an internal atmosphere of the chamber was formed in the same manner as in Example 1, in the first ignition mode for sputtering, RF power of 800 W and DC power of 500 W were simultaneously applied to the amorphous carbon target for 3 seconds, in the second ignition mode, RF power of 800 W and DC power of 1000 W were simultaneously applied to the amorphous carbon target for 5 seconds, and in the deposition mode, RF power of 800 W and DC power of 1000 W were simultaneously applied to the amorphous carbon target for 400 seconds to perform the sputtering.

As a result of the sputtering, the amorphous carbon film was deposited on the substrate, and a deposition thickness was measured to be 3960 Å.

The RF power and the DC power applied to the amorphous carbon target for each mode of Examples 1 and 2 and Comparative Examples 1 and 2 are shown in Table 1 below.

TABLE 1

| | | First | Second | |
|---|---|---|---|---|
| | | ignition | ignition | Deposition |
| Note | Condition | mode | mode | mode |
| Comparative | RF power (W) | 0 | 300 | 300 |
| Example 1 | DC power (W) | 1500 | 1500 | 1500 |
| | Time (sec) | 3 | 5 | 400 |
| Example 1 | RF power (W) | 600 | 600 | 600 |
| | DC power (W) | 500 | 0 | 0 |
| | Time (sec) | 3 | 5 | 400 |
| Example 2 | RF power (W) | 800 | 800 | 800 |
| | DC power (W) | 500 | 0 | 0 |
| | Time (sec) | 3 | 5 | 400 |
| Comparative | RF power (W) | 800 | 800 | 800 |
| Example 2 | DC power (W) | 500 | 1000 | 1000 |
| | Time (sec) | 3 | 5 | 400 |

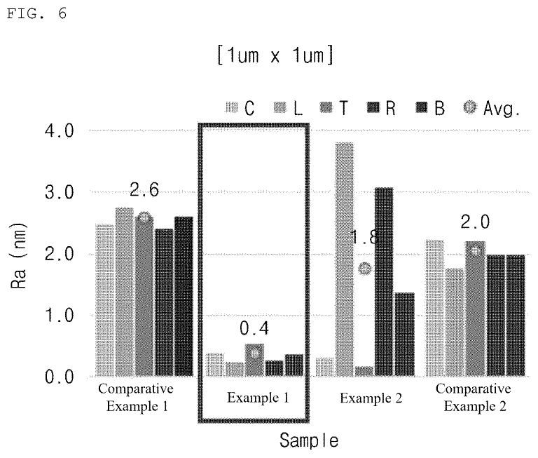

FIG. 5 is cross-sectional and surface images of an amorphous carbon film deposited according to Examples 1 and 2 and

Comparative Examples 1 and 2 of the present invention, which is photographed using an electron microscope.

Referring to FIG. 5, it was confirmed that the thickness of the amorphous carbon film deposited according to Example 2 and Comparative Example 2, in which the amount of RF power applied was the largest, was the largest. In this case, referring to Example 2 and Comparative Example 2, it was confirmed that the thickness of the amorphous carbon film deposited according to Comparative Example 2, in which the amount of applied DC power is relatively large, was larger than the thickness of the amorphous carbon film deposited according to Example 2 under the condition in which the amount of applied RF power is the same, but it was confirmed that the thickness increase rate due to the amount of applied DC power was not large.

That is, it was confirmed that the deposition thickness of the amorphous carbon film depends on the RF power rather than the DC power.

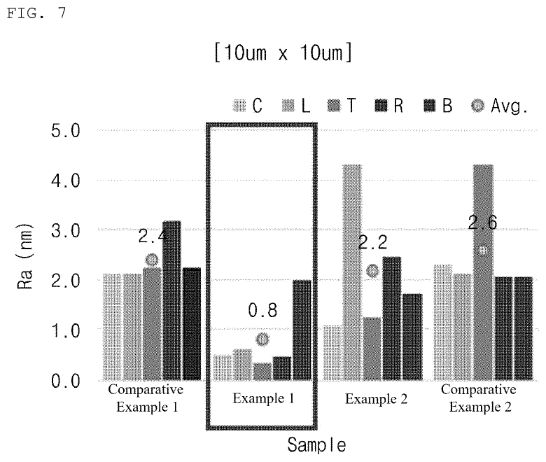

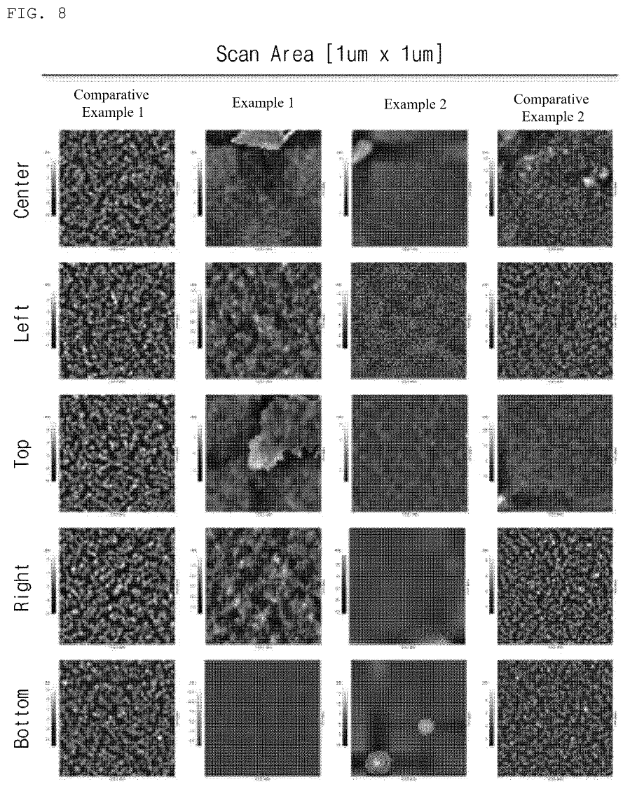

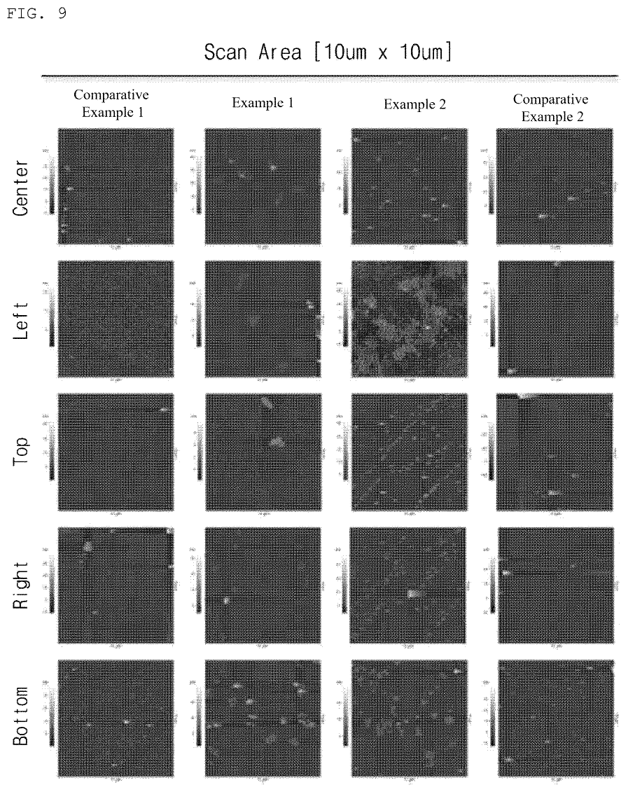

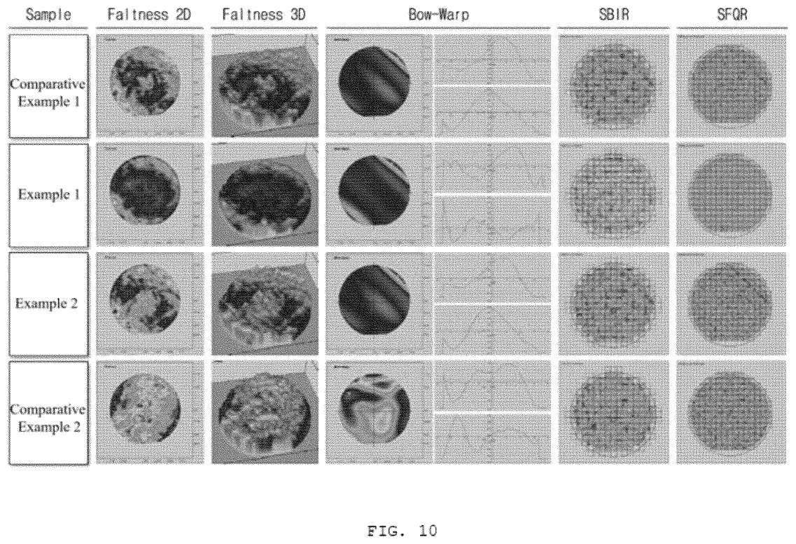

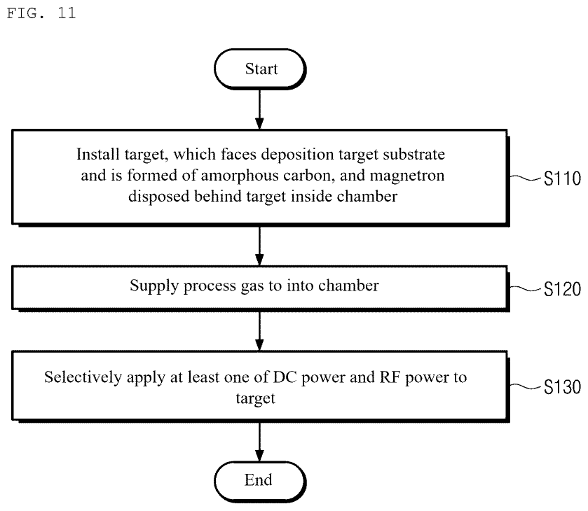

FIGS. 6 and 7 are results of measuring a surface roughness for each area of the amorphous carbon film deposited according to Examples 1 and 2 and Comparative Examples 1 and 2 of the present invention, and FIGS. 8 and 9 are surface scan images for each area of the amorphous carbon film deposited according to Examples 1 and 2 and Comparative Examples 1 and 2 of the present invention.

Referring to FIGS. 6 to 9, it was confirmed that the surface roughness Ra of the amorphous carbon film deposited according to Example 1 was the lowest.

In this case, it was confirmed that the surface roughness Ra of the amorphous carbon film deposited according to Example 1 was reduced as the area of the amorphous carbon film decreased, that is, as the surface roughness measurement area decreased.

Based on the area of the amorphous carbon film deposited according to Example 1 of 1 μm to 10 μm×1 μm to 10 μm, the surface roughness Ra was measured to be 4Å to 8Å.

In addition, FIG. 10 is a Tropel (Warp/Bow/SBIR/SFOR/TTV) analysis result of the amorphous carbon film deposited according to Examples 1 and 2 and Comparative Examples 1 and 2 of the present invention.

Referring to FIG. 10, it was analyzed that the amorphous carbon film deposited according to Example 1 had the best flatness, and the thickness deviation for each region was also the smallest.

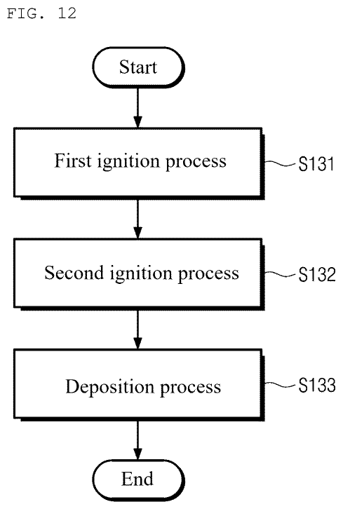

Hereinafter, a magnetron sputtering method for an amorphous carbon film according to one embodiment of the present invention will be described with reference to FIGS. 11 and 12. In this case, reference numerals of each component refer to FIG. 1.

FIG. 11 is a flowchart showing a process procedure of a magnetron sputtering method for an amorphous carbon film according to one embodiment of the present invention, and FIG. 12 is a flowchart sequentially showing a detailed process of step S130 of FIG. 11.

Referring to FIG. 11, the magnetron sputtering method for an amorphous carbon film according to one embodiment of the present invention may include steps S110, S120, and S130.

### Step S110

Step S110 is a step of installing the target 121 formed of amorphous carbon and the magnetron 122 inside the chamber 110.

To this end, in step S110, the target 121 may be installed to face the deposition target substrate S supported by a substrate holder (not shown) inside the chamber 110. In this case, in step S110, the target 121 having a relatively larger area than the deposition target substrate S may be prepared and installed to face the deposition target substrate S.

In addition, in step S110, the magnetron 122 may be installed behind the target 121 that is installed to face the deposition target substrate S. Accordingly, a magnetic field may be generated near the surface of the target 121 facing the deposition target substrate S.

As described above, the magnetic field generated by the magnetron 122 may trap the ionized process gas, for example, argon (Ar) ions and electrons, near the surface of the target 121 facing the deposition target substrate S to generate plasma.

Accordingly, a density of plasma may be increased near the surface of the target 121 facing the deposition target substrate S.

In this way, a deposition rate may be improved by the plasma density increased by the magnetic field.

### Step S120

Step S120 is a step of supplying a process gas into the chamber 110. According to one embodiment of the present invention, in step S120, first, a vacuum pump (not shown) may be operated to create a vacuum atmosphere inside the chamber 110.

Next, in step S120, the process gas may be supplied into the chamber 110 through the gas inlet 111 provided on one side of the chamber 110.

For example, in step S120, an argon (Ar) gas may be supplied into the chamber 110 as the process gas.

### Step S130

Step S130 is a step of generating plasma by generating a discharge between the target 121 and the deposition target substrate S, thereby forming the amorphous carbon film CF, which is a deposition film formed of a material constituting the target 121 on the deposition target substrate S, that is, amorphous carbon, on the deposition target substrate S.

In this case, according to one embodiment of the present invention, in step S130, at least one of DC power and RF power may be selectively applied to the target 121.

Referring to FIG. 12, step S130 may include a first ignition process S131, a second ignition process S132, and a deposition process S133.

First, in the first ignition process S131, the DC power and the RF power may be simultaneously applied to the target 121.

In this case, the RF power applied to the target 121 may be relatively greater than the DC power simultaneously applied.

For example, in the first ignition process S131, when RF power of 600 W is applied to the target 121, DC power of 500 W may be simultaneously applied to the target 121 for 3 seconds.

Next, in the second ignition process S132, only the RF power may be applied to the target 121.

For example, in the second ignition process S132, RF power of 600 W may be applied to the target 121 for 5 seconds, and in this case, the DC power applied to the target 121 may be zero.

Finally, as in the second ignition process S132, only the RF power may be applied to the target 121 in the deposition process S133.

For example, in the deposition process S133, RF power of 600 W may be applied to the target 121 for 400 seconds, and in this case, the DC power applied to the target 121 may be zero.

When the deposition process S133 is completed, the amorphous carbon film CF having a surface roughness Ra in a range of 4 Å to 8 Å, which is usable as the photoresist PR of the chemical etching process, may be formed on the deposition target substrate S.

While the present invention has been described in connection with the embodiments, it is not to be limited thereto but will be defined by the appended claims. In addition, it is to be understood that those skilled in the art can substitute, change, or modify the embodiments in various forms without departing from the scope and spirit of the present invention.

1. A magnetron sputtering device for an amorphous carbon film, the magnetron sputtering device comprising:
a chamber having an inside maintained in a vacuum state and including a gas inlet through which a process gas is introduced and a gas outlet through which the process gas is discharged;
a target unit including a target provided to face a deposition target substrate disposed inside the chamber and formed of amorphous carbon, and a magnetron disposed rearward of the target; and
a control unit configured to selectively apply at least one of DC power and RF power to the target,
wherein a deposition film formed of the amorphous carbon is formed on the deposition target substrate through a first ignition mode, a second ignition mode, and a deposition mode which are sequentially switched, and
the control unit simultaneously applies the DC power and the RF power to the target in the first ignition mode, and applies only the RF power to the target in the second ignition mode and the deposition mode.

2. The magnetron sputtering device of claim 1, wherein, among the first ignition mode, the second ignition mode, and the deposition mode, a time of the first ignition mode is shortest and a time of the deposition mode is longest.

3. The magnetron sputtering device of claim 1, wherein in the first ignition mode, the RF power applied to the target is relatively greater than the DC power applied to the target, and
in the first ignition mode, the second ignition mode, and the deposition mode, magnitudes of the RF power applied to the target are all the same.

4. The magnetron sputtering device of claim 1, wherein a surface roughness (Ra) of the deposition film is in a range of 4 Å to 8 Å.

5. The magnetron device of claim 4, wherein the surface roughness (Ra) is reduced as an area of the deposition film decreases.

6. A photoresist amorphous carbon film, which is deposited on a deposition target substrate through the magnetron sputtering device of claim 1, and has a surface roughness (Ra) in a range of 4 Å to 8 Å.

7. A magnetron sputtering method for an amorphous carbon film, the magnetron sputtering method comprising:
installing a target, which faces a deposition target substrate and is formed of amorphous carbon, and a magnetron disposed rearward of the target inside the chamber;
supplying a process gas into the chamber; and
selectively applying at least one of DC power and RF power to the target,
wherein the selectively applying of the at least one power includes:
a first ignition process of simultaneously applying the DC power and the RF power to the target;
a second ignition process of applying only the RF power to the target after the first ignition process; and
a deposition process of continuously applying only the RF power to the target after the second ignition process.
